(19) United States
(12) Patent Application Publication
(10) Pub. No.: US 2009/0242240 A1
(43) Pub. Date: Oct. 1, 2009

(54) Flexible circuit board, flexible circuit board positioning method, flexible circuit board positioning structure, droplet ejection head and image forming device

(75) Inventor: Tsutomu Yokouchi, Kanagawa (JP)

Correspondence Address: AKERMAN SENTERFITT, 8100 BOONE BOULEVARD, SUITE 700, VIENNA, VA, 22182-2683, US

(73) Assignee: FUJIFILM Corporation, Tokyo (JP)

(21) Appl. No.: 12/382,802

(22) Filed: Mar. 24, 2009

(30) Foreign Application Priority Data
Mar. 27, 2008 (JP) 2008-082980

(51) Int. Cl. H05K 1/00; B41J 2/015

(52) U.S. Cl. 174/254; 347/20

(57) ABSTRACT

A flexible circuit board with which positioning relative to a corresponding member is easy, a flexible circuit board positioning method for positioning the flexible circuit board at the corresponding member, a flexible circuit board positioning structure that positions the flexible circuit board at the corresponding member, a droplet ejection head that employs the flexible circuit board, and an image forming device that employs the droplet ejection head. A positioning hole in the flexible circuit board is configured with a broad portion at a leading end side with respect to a direction of movement at a time of positioning. Even if the positioning hole is offset in a lateral direction relative to a positioning pin, this offset is absorbed and the positioning pin can be accommodated in the positioning hole.

### CROSS-REFERENCE TO RELATED APPLICATION

This application claims priority under 35 USC 119 from Japanese Patent Application No. 2008-082980, the disclosure of which is incorporated by reference herein.

### BACKGROUND OF THE INVENTION

1. Field of the Invention

The present invention relates to a flexible circuit board, a flexible circuit board positioning method for positioning the flexible circuit board at a corresponding member, a flexible circuit board positioning structure that positions the flexible circuit board at a corresponding member, a droplet ejection head that employs the flexible circuit board, and an image forming device that employs the droplet ejection head.

2. Description of the Related Art

Japanese Patent Application Laid-Open (JP-A) No. 2007-36009 is an example of a connection structure that connects a flexible circuit board to an electronic component (a corresponding member). JP-A No. 2007-36009 describes a constitution in which a through hole is provided at a position of wiring of a flexible circuit board that is to be connected with the electronic component, a protruding portion of the electronic component is inserted into the through hole, and the flexible circuit board and electronic component are electronically connected.

However, because a flexible circuit board has flexibility, the flexible circuit board may deform and positioning relative to the corresponding member becomes difficult. For example, in the constitution of JP-A No. 2007-36009, accurate positioning between the through hole in the wiring and the protruding portion of the electronic component is necessary. However, there are no descriptions relating to this positioning in JP-A No. 2007-36009.

### SUMMARY OF THE INVENTION

The present invention is to provide a flexible circuit board with which positioning relative to a corresponding member is easy, a flexible circuit board positioning method that positions the flexible circuit board relative to a corresponding member, a flexible circuit board positioning structure that positions the flexible circuit board relative to a corresponding member, a droplet ejection head that employs the flexible circuit board, and an image forming device that employs the droplet ejection head.

A first aspect of the present invention is a flexible circuit board including: a flexible circuit board; and a positioning accommodation portion, formed at the flexible circuit board body, capable of accommodating a positioning protrusion portion provided at a corresponding member, to which the flexible circuit board body is joined, the positioning accommodation portion positioning the flexible circuit board body relative to the corresponding member, wherein a broad portion is formed at the positioning accommodation portion, at which a leading end side of the positioning accommodation portion, with respect to a direction of movement of the flexible circuit board body relative to the corresponding member at a time of joining, is broader than a trailing end side.

With the flexible circuit board of the first aspect of the present invention, the positioning protrusion portion of the corresponding member is accommodated in the positioning accommodation portion of the flexible circuit board body. Due thereto, the flexible circuit board body is positioned relative to the corresponding member. Here, when the flexible circuit board is to be positioned relative to the corresponding member, for example, the flexible circuit board positioning method of a seventh aspect may be employed. The seventh aspect of the present invention is a flexible circuit board positioning method for positioning a flexible circuit board at a corresponding member, the flexible circuit board including, a flexible circuit board body; and a positioning accommodation portion, formed at the flexible circuit board body, capable of accommodating a positioning protrusion portion provided at a corresponding member, to which the flexible circuit board body is joined, the positioning accommodation portion positioning the flexible circuit board body relative to the corresponding member, wherein a broad portion is formed at the positioning accommodation portion, at which a leading end side of the positioning accommodation portion, with respect to a direction of movement of the flexible circuit board body relative to the corresponding member at a time of joining, is broader than a trailing end side, the flexible circuit board positioning method including: accommodating the positioning protrusion portion in the broad portion by moving the moving the flexible circuit board relative to the corresponding member; and positioning by moving the flexible circuit board further relative to the corresponding member and causing the trailing end side of the positioning accommodation portion to make contact with the positioning protrusion portion.

That is, in the accommodation step, the positioning protrusion portion is accommodated in the positioning accommodation portion while the flexible circuit board is being moved relative to the corresponding member. The broad portion is formed in the positioning accommodation portion, at which broad portion the movement direction leading end side is broadened relative to the trailing end side. Therefore, the positioning protrusion portion may initially be accommodated in the broad portion. Then, in the positioning step, the flexible circuit board is moved further relative to the corresponding member. Due thereto, the trailing end side of the accommodation portion (which is made relatively narrower than the broad portion) comes into contact with the positioning protrusion portion, and the flexible circuit board is positioned relative to the corresponding member.

Thus, in the flexible circuit board of the present invention, the broad portion is formed in the positioning accommodation portion of the flexible circuit board body. In consequence, positioning may be carried out with ease by initially accommodating the positioning protrusion portion of the corresponding member in the broad portion.

A second aspect of the present invention may be the above-described first aspect in which a surface contact portion, which makes surface contact with the positioning protrusion portion, is formed at the trailing end side of the positioning accommodation portion.

Consequently, at the trailing end side of the positioning accommodation portion, the surface contact portion makes surface contact with the positioning protrusion portion. Thus, a contact area can be increased relative to a structure in which point contact or line contact is made rather than surface contact. Therefore, a local load on the positioning accommodation portion from the positioning protrusion portion can be restrained.

A third aspect of the present invention may be the above-described second aspect in which the surface contact portion includes a circular arc face that makes surface contact, with a radius of curvature the same as the radius of curvature of an outer peripheral face of the positioning protrusion portion, which is formed in a circular rod shape.

That is, if the positioning protrusion portion is formed in a circular rod shape, the surface contact portion is configured with a simple structure just by forming a circular arc face with the same radius of curvature as the outer peripheral face of the protrusion portion. Due thereto, a large area of contact with the positioning protrusion portion is assured.

A fourth aspect of the present invention may be the above-described first to third aspects in which a lateral direction contact portion is formed at the trailing end side of the positioning accommodation portion, the lateral direction contact portion making contact with the positioning protrusion portion in a lateral direction of the flexible circuit board, which intersects the movement direction.

Consequently, when the flexible circuit board acts to move in the lateral direction of the flexible circuit board relative to the corresponding member, the lateral direction contact portion comes into contact with the positioning protrusion portion. Due thereto, movement in the lateral direction of the flexible circuit board is blocked. Thus, positioning in the lateral direction of the flexible circuit board relative to the corresponding member is possible.

A fifth aspect of the present invention may be the above-described first to fourth aspects in which at least one of the positioning accommodation portion is formed at each of a lateral direction middle region of the flexible circuit board body, which lateral direction intersects the movement direction, and two lateral direction end sides relative to the middle region.

Hence, both the lateral direction end regions of the flexible circuit board body and the lateral direction middle region may be positioned. Thus, deformation at the lateral direction middle region is suppressed when, for example, the flexible circuit board body is joined to the corresponding member. Due thereto, offsetting of a joining position of the flexible circuit board may be suppressed.

A sixth aspect of the present invention may be the above-described fifth aspect in which a portion at the trailing end side of at least one of the plurality of positioning accommodation portions is a second broad portion, which is formed to be broader in the lateral direction than a portion at the trailing end side of another of the positioning accommodation portions.

Thus, at one or more of the positioning accommodation portions, the trailing end region is broadly formed and the second broad portion is structured. Hence, if a relative positioning accuracy of the positioning accommodation portion with the positioning protrusion portion is poor, a lateral direction offset of the positioning protrusion may be tolerated at the second broad portion. Therefore, positioning of the flexible circuit board is possible. Among the positioning accommodation portions, there is at least one positioning accommodation portion at which this second broad portion is not formed at the trailing end side. Accordingly, assured positioning in the lateral direction of the flexible circuit board, by the positioning accommodation portion(s) at which the second broad portion is not formed and the positioning protrusion portions, is enabled.

An eighth aspect of the present invention is a flexible circuit board positioning structure including: a flexible circuit board including a flexible circuit board body, and a positioning accommodation portion, formed at the flexible circuit board body, capable of accommodating a positioning protrusion portion provided at a corresponding member, to which the flexible circuit board body is joined, the positioning accommodation portion positioning the flexible circuit board body relative to the corresponding member, wherein a broad portion is formed at the positioning accommodation portion, at which a leading end side of the positioning accommodation portion, with respect to a direction of movement of the flexible circuit board body relative to the corresponding member at a time of joining, is broader than a trailing end side; the corresponding member to which the flexible circuit board body is to be joined; and the positioning protrusion portion provided at the corresponding member, wherein the trailing end side of the positioning accommodation portion of the flexible circuit board body is positioned by coming into contact with the positioning protrusion portion.

A flexible circuit board body of the first to sixth aspects is employed in the flexible circuit board positioning structure of the eighth aspect of the present invention. With this flexible circuit board positioning structure, at the corresponding member, the positioning protrusion portion is initially accommodated at the broad portion. Then the trailing end portion of the accommodation portion comes into contact with the positioning protrusion portion, and the flexible circuit board is positioned relative to the corresponding member.

Thus, because the flexible circuit board in which the broad portion is formed at the positioning accommodation portion is employed, positioning may be carried out with ease.

A ninth aspect of the present invention is a droplet ejection head including: a droplet ejection head body for ejecting droplets; a circuit substrate provided at the droplet ejection head body; and a flexible circuit board joined to the circuit substrate, the flexible circuit board including a flexible circuit board body, and a positioning accommodation portion, formed at the flexible circuit board body, capable of accommodating a positioning protrusion portion provided at the circuit substrate, to which the flexible circuit board body is joined, the positioning accommodation portion positioning the flexible circuit board body relative to the circuit substrate, wherein a broad portion is formed at the positioning accommodation portion, at which a leading end side of the positioning accommodation portion, with respect to a direction of movement of the flexible circuit board body relative to the circuit substrate at a time of joining, is broader than a trailing end side.

The droplet ejection head of the ninth aspect of the present invention includes the circuit substrate to which the flexible circuit board is connected, and the flexible circuit board may be positioned with ease relative to the circuit substrate (i.e., the circuit substrate or a component on the circuit substrate serves as the corresponding member). In the state in which the flexible circuit board is connected to the circuit substrate, the droplet ejection head body may be driven or controlled and droplets ejected.

A tenth aspect of the present invention may be the above-described ninth aspect in which an image forming device includes: a conveyance apparatus that conveys a recording sheet; and the droplet ejection head according to the ninth aspect, which ejects droplets onto the recording sheet conveyed by the conveyance apparatus.

Therefore, while the sheet member is being conveyed by the conveyance apparatus, droplets may be ejected from the droplet ejection head onto the recording sheet and an image may be formed.

According to the aspects described above, the present invention provides a flexible circuit board with which positioning relative to a corresponding member is easy, a flexible circuit board positioning method for positioning a flexible circuit board relative to a corresponding member, a flexible circuit board positioning structure that positions a flexible circuit board relative to a corresponding member, a droplet ejection head that employs the flexible circuit board, and an image forming device that employs the droplet ejection head.

### BRIEF DESCRIPTION OF THE DRAWINGS

Exemplary embodiments of the present invention will be described in detail based on the following figures, wherein:

FIG. 1 is a schematic structural diagram showing an image forming device of a first exemplary embodiment of the present invention;

FIG. 2 is a schematic perspective diagram showing a head unit of the image forming device of the first exemplary embodiment of the present invention;

FIG. 3A is a sectional view partially showing a flexible circuit board of the first exemplary embodiment of the present invention and an electronic component in a state before positioning;

FIG. 3B is a plan view showing, magnified, a vicinity of a positioning hole of the flexible circuit board;

FIG. 4 is a plan view partially showing the flexible circuit board of the first exemplary embodiment of the present invention;

FIG. 5A is a sectional view showing a process of positioning the flexible circuit board of the first exemplary embodiment of the present invention relative to an electronic component;

FIG. 5B is a plan view showing the process of positioning the flexible circuit board of the first exemplary embodiment of the present invention relative to the electronic component;

FIG. 6A is a sectional view showing the process of positioning the flexible circuit board of the first exemplary embodiment of the present invention relative to the electronic component;

FIG. 6B is a plan view showing the process of positioning the flexible circuit board of the first exemplary embodiment of the present invention relative to the electronic component;

FIG. 7A is a sectional view showing the process of positioning the flexible circuit board of the first exemplary embodiment of the present invention relative to the electronic component;

FIG. 7B is a plan view showing the process of positioning the flexible circuit board of the first exemplary embodiment of the present invention relative to the electronic component;

FIG. 8 is a sectional view partially showing a flexible circuit board and an electronic component of a comparative example;

FIG. 9 is a sectional view partially showing the flexible circuit board of the first exemplary embodiment of the present invention and an electronic component in a state after positioning;

FIG. 10 is a plan view partially showing a flexible circuit board of a second exemplary embodiment of the present invention;

FIG. 11 is a plan view showing a state in which middle of a lateral direction of a flexible circuit board is deformed;

FIG. 12 is a plan view partially showing a flexible circuit board of a third exemplary embodiment of the present invention;

FIG. 13 is a plan view partially showing a flexible circuit board of a fourth exemplary embodiment of the present invention;

FIG. 14 is a plan view showing an example of positioning pins to which the present invention is applicable, together with a flexible circuit board; and

FIG. 15 is a plan view showing an example of positioning pins to which the present invention is applicable, together with a flexible circuit board.

### DETAILED DESCRIPTION OF THE INVENTION

### First Embodiment

Herebelow, an image forming device relating to an exemplary embodiment of the present invention is described.

Firstly, overall structure of an image forming device 10 is described.

### —Image Forming Device—

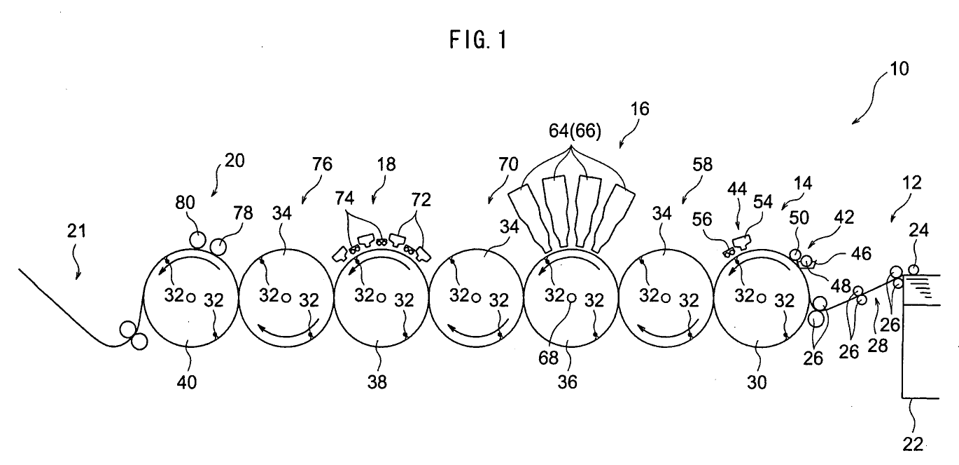

As shown in FIG. 1, the image forming device 10 relating to the present exemplary embodiment is provided with a paper supply conveyance section 12 that supplies and conveys sheet paper which serves as a recording medium (hereinafter referred to as paper), at an upstream side of a conveyance direction of the paper. Along the conveyance direction of the paper at the downstream side of the paper supply conveyance section 12, a processing liquid application section 14, an image forming section 16, an ink drying section 18, an image fixing section 20 and an ejection section 21 are provided. The processing liquid application section 14 applies a processing liquid to a recording face of the paper. The image forming section 16 forms an image on the recording face of the paper. The ink drying section 18 dries ink of the image formed on the recording face. The image fixing section 20 fixes the dried ink to the paper. The ejection section 21 ejects the paper to which the image has been fixed.

Each processing section is described herebelow.

### —Paper Supply Conveyance Section—

The paper supply conveyance section 12 is provided with a stacking section 22, at which paper is stacked, and a paper supply section 24 at the paper conveyance direction downstream side of the stacking section 22. The paper supply section 24 supplies the paper stacked in the stacking section 22, one sheet at a time. The paper supplied by the paper supply section 24 passes through a conveyance section 28 structured with plural pairs of rollers 26, and is conveyed to the processing liquid application section 14.

### —Processing Liquid Application Section—

At the processing liquid application section 14, a processing liquid application drum 30 is rotatably provided. Retention members 32 are provided at the processing liquid application drum 30. The retention members 32 nip the distal end portions of the paper and retain the paper. In a state in which paper is retained at the surface of the processing liquid application drum 30, between the retention members 32, the processing liquid application drum 30 conveys the paper to the downstream side, by rotation of the processing liquid application drum 30.

Similarly to the processing liquid application drum 30, the retention members 32 are also provided at an intermediate conveyance drum 34, an image forming drum 36, an ink drying drum 38 and a fixing drum 40, which will be described later. The retention members 32 handovers the paper from upstream side drums to downstream side drums.

At an upper portion of the processing liquid application drum 30, a processing liquid application apparatus 42 and a processing liquid drying apparatus 44 are disposed along the circumferential direction of the processing liquid application drum 30. The processing liquid application apparatus 42 applies processing liquid to the recording face of the paper. Then, the processing liquid is dried by the processing liquid drying apparatus 44.

This processing liquid will react with ink and coagulate a colorant (pigment), and has the effect of promoting separation of the colorant (pigment) from a solvent. A reservoir section 46, at which the processing liquid is stored, is provided at the processing liquid application apparatus 42. A portion of a gravure roller 48 is immersed in the processing liquid.

A rubber roller 50 is disposed to press against the gravure roller 48. The rubber roller 50 touches against the recording face (surface) of the paper and applies the processing liquid thereto. Further, a squeegee (not shown) touches against the gravure roller 48, and regulates processing liquid application amounts that are applied to the recording face of the paper.

Ideally, layer thickness of a processing liquid is significantly smaller than the diameter of droplets (below referred to as head jet droplets) jetted from an inkjet line head 64, which will be described later. That is, if the thickness of the processing liquid layer is thick, ink dots will float in the processing liquid and will not contact with the recording face of the paper. For example, in a case of 2 pl droplet amounts, an average diameter of the head jet droplets is 15.6 μm. Here, with droplets of this order of size (volume), if the thickness of the processing liquid layer is thick, the ink dots will float in the processing liquid and will not contact with the recording face of the paper. For impact dot diameters (diameters of the droplets that have made contact with the recording face of the paper) of 30 μm or above from 2 pl droplet amounts, it is preferable for the thickness of the processing liquid layer to be not more than 3 μm.

At the processing liquid drying apparatus 44, a hot wind nozzle 54 and an infrared heater 56 (below referred to as the IR heater 56) are disposed close to the surface of the processing liquid application drum 30. A solvent such as water or the like in the processing liquid is evaporated by the hot wind nozzle 54 and the IR heater 56, forming solids or a thin processing liquid layer at the recording face of the paper. Because the processing liquid is formed into a thin layer by this processing liquid drying process, dots of ink jetted by the image forming section 16 will come into contact with the paper surface and a required dot diameter will be obtained. In addition, because the processing liquid is formed into a thin layer, the action of the ink reacting with the thinned processing liquid and the colorant coagulating and being fixed to the paper surface is easily obtained.

Hence, the paper at whose recording face the processing liquid has been applied and dried by the processing liquid application section 14 is conveyed to an intermediate conveyance section 58, which is disposed between the processing liquid application section 14 and the image forming section 16.

### —Intermediate Conveyance Section—

At the intermediate conveyance section 58, the intermediate conveyance drum 34 is rotatably provided. The intermediate conveyance drum 34 retains the paper at the surface thereof, by the retention members 32 that are provided at the intermediate conveyance drum 34. Then, the intermediate conveyance section 58 conveys the paper downstream by rotation of the intermediate conveyance drum 34.

### —Image Forming Section—

At the image forming section 16, the image forming drum 36 is rotatably provided. The image forming drum 36 retains the paper at the surface thereof, between the retention members 32 that are provided at the image forming drum 36. Then, the image forming section 16 conveys the paper downstream by rotation of the image forming drum 36.

A head unit 66 is disposed close to the surface of the image forming drum 36 at an upper portion of the image forming drum 36. The head unit 66 is configured as a single pass-type inkjet line heads 64. At the head unit 66, at least inkjet line heads 64 of Y, M, C and K, which are the basic colors, are arranged along the circumferential direction of the image forming drum 36. The head unit 66 forms an image of the respective colors on the processing liquid layer that has been formed at the recording face of the paper by the processing liquid application section 14. Structure of the head unit 66 will be described hereafter.

The processing liquid has an effect of coagulating colorant (pigment) and latex particles dispersed in the ink with the processing liquid. The processing liquid forms coagulated bodies that will not form colorant flowing on the paper. As an example of the reaction between the ink and the processing liquid, a mechanism is utilized that disrupts pigment dispersion and causes coagulation by lowering the pH value with an acid included in the processing liquid. Due thereto, the processing liquid prevents colorant bleeding, color mixing between inks of the different colors, and droplet interference due to liquid mixing when the ink droplets impact.

Each inkjet line head 64 performs jetting synchronously with an encoder (not shown) that senses a rotation speed, which is provided at the image forming drum 36. Due thereto, the inkjet line head 64 may determine impact positions of the ink with high accuracy and may reduce impact variations due to vibrations of the image forming drum 36, precision of a rotation axle 68 and drum surface speeds.

The head unit 66 may be structured to be capable of withdrawing from the upper portion of the image forming drum 36. Maintenance operations such as cleaning nozzle faces of the inkjet line heads 64, ejecting increased-viscosity ink and the like are carried out with the head unit 66 withdrawn from the upper portion of the image forming drum 36.

The paper at whose recording face the image has been formed is conveyed to an intermediate conveyance section 70, which is disposed between the image forming section 16 and the ink drying section 18, by the rotation of the image forming drum 36. Here, the intermediate conveyance section 70 has substantially the same structure as the intermediate conveyance section 58, and therefore, explanation thereof will be omitted.

### —Ink Drying Section—

At the ink drying section 18, the ink drying drum 38 is rotatably provided. At an upper portion of the ink drying drum 38, a hot wind nozzle 72 and an IR heater 74 are plurally disposed close to a surface of the ink drying drum 38. At an image formation portion of the paper, solvent that has been separated by the colorant coagulation action is dried off by hot airflow from the hot wind nozzle 72 and IR heater 74, and a thin film image layer is formed.

The hot wind will vary with the conveyance speed of the paper, but ordinarily will be set to between 50° C. and 70° C. The evaporated solvent is ejected outside the image forming device 10 together with air, and the evaporated solvent is recovered. This solvent may be cooled by a cooler, a radiator or the like and may be recovered as a liquid.

The paper at which the image on the recording face has been dried is conveyed to an intermediate conveyance section 76, which is disposed between the ink drying section 18 and the image fixing section 20, by the rotation of the ink drying drum 38. Here, the intermediate conveyance section 76 has substantially the same structure as the intermediate conveyance section 58, and therefore, explanation thereof will be omitted.

### —Image Fixing Section—

At the image fixing section 20, the fixing drum 40 is rotatably provided. In the image fixing section 20, latex particles in the thin-film image layer formed on the ink drying drum 38 are heated/pressed and fused, and binded and fixed onto the paper.

At an upper portion of the fixing drum 40, a heating roller 78 is disposed close to the surface of the fixing drum 40. The heating roller 78 is configured with a halogen lamp inserted in a metal pipe of aluminum or the like that has good thermal conductivity. The heating roller 78 provides heat energy, to at least the glass transition temperature of the latex, to the recording paper. As a result, the latex particles fuse, are pushed into irregularities in the paper, and are fixed. In addition, the irregularities of the image surface are leveled and glossiness is obtained.

A fixing roller 80 is disposed downstream of the heating roller 78. The fixing roller 80 is disposed in a state of pressing against the surface of the fixing drum 40, and is structured so as to provide nipping force between the fixing roller 80 and the fixing drum 40. Accordingly, at least one of the fixing roller 80 and the fixing drum 40 has a resilient layer at the surface thereof and forms a structure with a uniform nipping pressure on the paper.

As described above, the paper to whose recording face the image has been fixed is conveyed by the rotation of the fixing drum 40 to the ejection section 21, which is disposed downstream of the image fixing section 20.

The image fixing section 20 has been described for this exemplary embodiment. However, it is sufficient if an image formed at a recording face by the ink drying section 18 can be dried and fixed. Therefore, the image fixing section 20 is not necessarily required.

### —Head Unit—

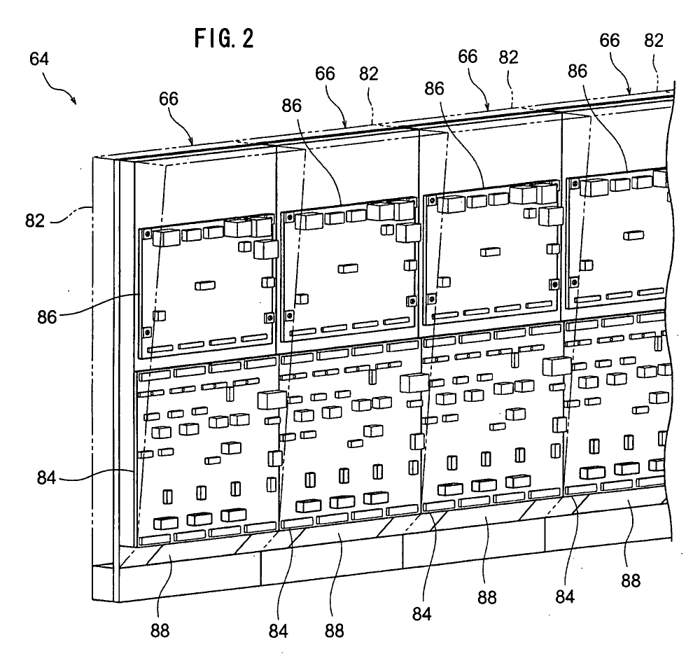

As is shown in FIG. 2, the head unit 66 includes a head casing 82. Driver circuit boards 84 and control circuit boards 86 are provided inside the head casing 82. The driver circuit boards 84 and the control circuit boards 86 perform, respectively, driving of the head unit 66 and various kinds of control, or the like. Specifically, plural nozzles are provided at a lower portion of the driver circuit board 84. The driver circuit board 84 drives piezoelectric elements which are provided in correspondence with the nozzles, and thus causes droplets to be ejected from the nozzles at the paper. In the present exemplary embodiment, as an example, a flexible circuit board 88 is positioned relative to the driver circuit board 84 and joined thereto.

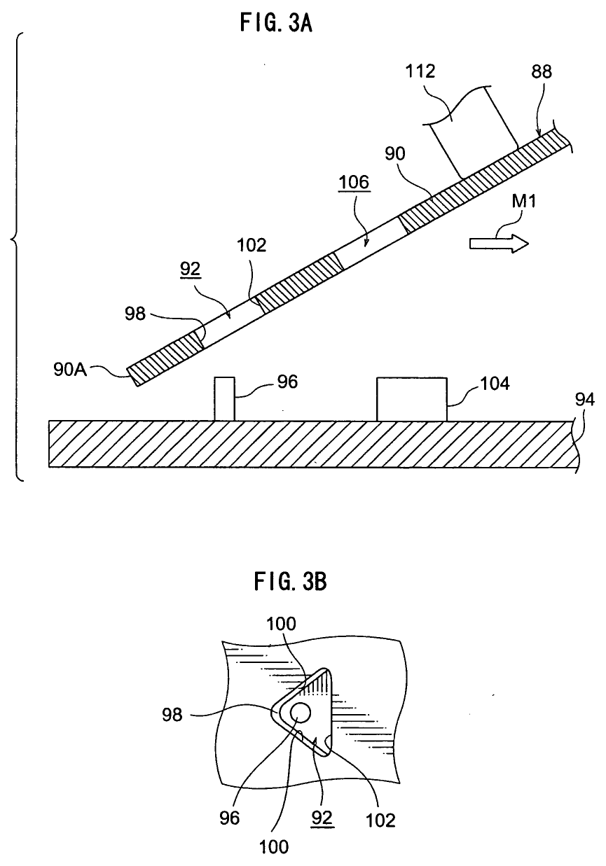

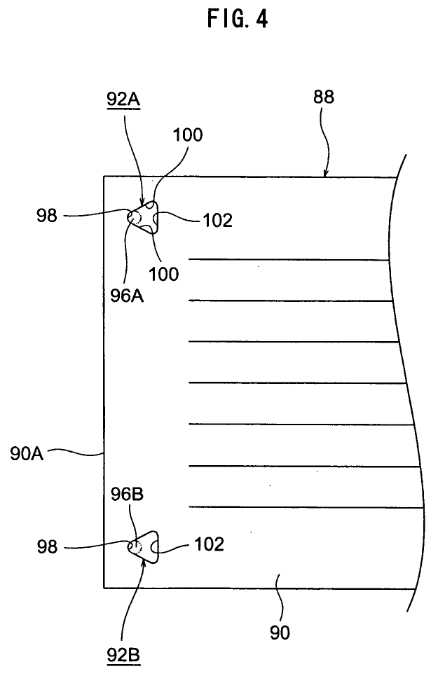

As shown in FIG. 3A, the flexible circuit board 88 includes a flexible circuit board body 90, which is formed substantially in a board shape of a material with flexibility, such as polyimide or the like. As shown in FIG. 4, positioning holes 92A and 92B are formed at positions in vicinities of two lateral direction ends of a length direction edge 90A of the flexible circuit board body 90. Only the edge 90A side of the flexible circuit board body 90 is shown in FIG. 3A and FIG. 4; the other edge side is not illustrated. Herebelow, the edge 90A of the flexible circuit board body 90 may be referred to simply as the “one edge”. Moreover, the lateral direction of the flexible circuit board body 90 may be referred to simply as the “lateral direction”.

As shown in FIG. 3A, positioning pins 96A and 96B are provided protruding from an electronic component 94 on the driver circuit board 84. The positioning pins 96A and 96B are in one-to-one correspondence with the positioning holes 92A and 92B, respectively. The positioning pins 96A and 96B are both formed in circular rod shapes, and heights thereof are greater than a thickness of the flexible circuit board 88.

In the following descriptions, where it is not necessary to particularly distinguish between the positioning holes 92A and 92B, a positioning hole 92 is referred to as appropriate. Similarly, where it is not necessary to particularly distinguish between the positioning pins 96A and 96B, a positioning pin 96 is referred to.

As can be seen from FIG. 3B and FIG. 4, the positioning holes 92A and 92B are both formed in isosceles triangle shapes which broaden from the one edge side towards the other edge side. The one edge sides of the positioning holes 92A and 92B are formed as circular arc faces 98 which are curved with a radius of curvature the same as that of outer peripheral surfaces of the positioning pins 96A and 96B. Therefore, when the positioning pins 96A and 96B are positioned at the one edge sides of the positioning holes 92A and 92B, the outer peripheral surfaces of the positioning pins 96A and 96B are in surface contact with the circular arc faces 98 of the positioning holes 92A and 92B. At this time, inner surfaces 100 of the positioning holes 92A and 92B oppose and make contact with the positioning pins 96A and 96B at angles to the lateral direction. Thus, relative movement between the positioning pins 96A and 96B and the positioning holes 92A and 92B in the lateral direction is blocked.

The widths of the positioning holes 92A and 92B gradually broaden towards the other edge side from the circular arc faces 98. At the other edge sides of the positioning holes 92A and 92B, broad portions 102 with widths wider than diameters of the positioning pins 96A and 96B are configured. As described later, in the present exemplary embodiment, the flexible circuit board 88 is moved relative to the electronic component 94 to carry out positioning. The broad portions 102 are formed at the leading end side with respect to this movement direction.

Portions disposed at the two sides of each broad portion 102 (i.e., of the three corners of each of the positioning holes 92A and 92B, the two corners other than the circular arc face 98) are also curved with a predetermined radius of curvature. Thus, shapes are formed in which there are no portions with local angularity.

As shown in FIG. 3A, a protrusion 104 for joining with the flexible circuit board 88 is formed at the electronic component 94. A joining hole 106 is formed in the flexible circuit board 88. The joining protrusion 104 mates with the joining hole 106 when the positioning pins 96A and 96B are in surface contact with the circular arc faces 98 of the positioning holes 92A and 92B, respectively.

In the present exemplary embodiment, the joining protrusion 104 has substantially the same external shape as the joining hole 106 or is formed a little smaller than the external shape of the joining hole 106. The joining protrusion 104 is insertable into the joining hole 106.

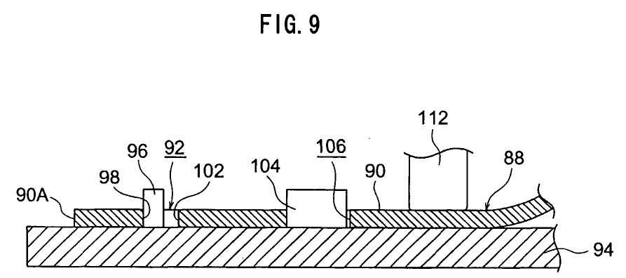

The joining protrusion 104 is formed such that a height thereof is greater than a thickness of the flexible circuit board body 90. Therefore, when the joining protrusion 104 has been inserted into the joining hole 106, an upper portion of the joining protrusion 104 protrudes from the joining hole 106 (from an upper face of the flexible circuit board body 90) and constitutes a protrusion portion (see FIG. 9).

When the flexible circuit board 88 has been joined to the electronic component 94, the protrusion portion is crimped and widened, structuring a wide diameter portion. This wide diameter portion partially overlaps with the flexible circuit board body 90, and the flexible circuit board body 90 is sandwiched between the electronic component 94 and the wide diameter portion, by what is known as an anchoring effect. Hence, the flexible circuit board 88 and the electronic component 94 are assuredly fixed. Moreover, the flexible circuit board 88 and the electronic component 94 are electrically connected.

Next, a method for positioning the flexible circuit board 88 relative to the electronic component 94 (i.e., the driver circuit board 84) and joining the same will be described.

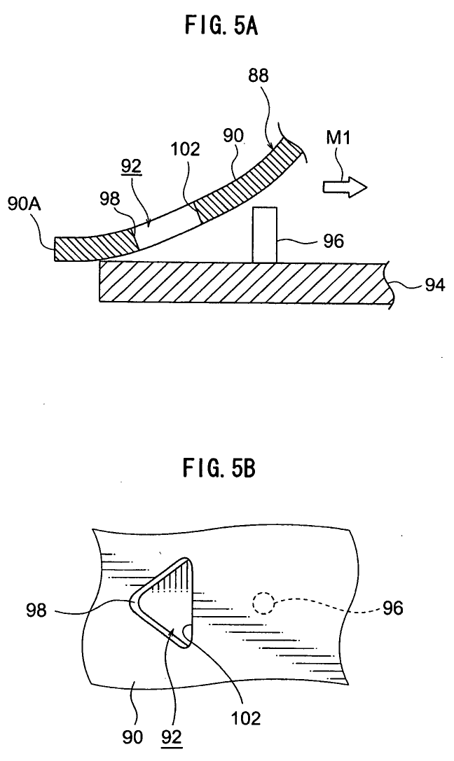

Firstly, as shown in FIG. 5A and FIG. 5B, the flexible circuit board body 90 is put against the electronic component 94 such that the positioning holes 92A and 92B are disposed to the edge 90A side (the opposite side from the direction of arrow M1) relative to the two positioning pins 96A and 96B. Then, the flexible circuit board body 90 is flexed toward the electronic component 94 by a pushing jig 112 (not illustrated in FIG. 5A to FIG. 7B but see FIG. 3A) while being moved in the direction of arrow M1.

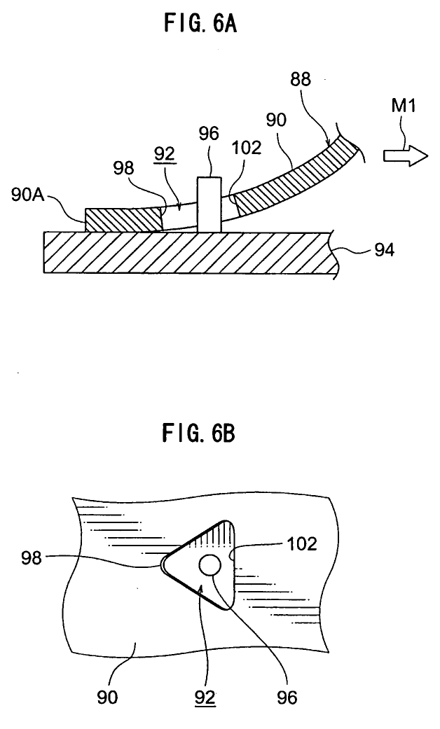

As shown in FIG. 6A and FIG. 6B, when the flexible circuit board body 90 is moved in the direction of arrow M1, the broad portions 102 of the positioning holes 92A and 92B reach positions of the positioning pins 96A and 96B or positions close thereto, and the positioning pins 96A and 96B enter into the positioning holes 92A and 92B (an accommodation step).

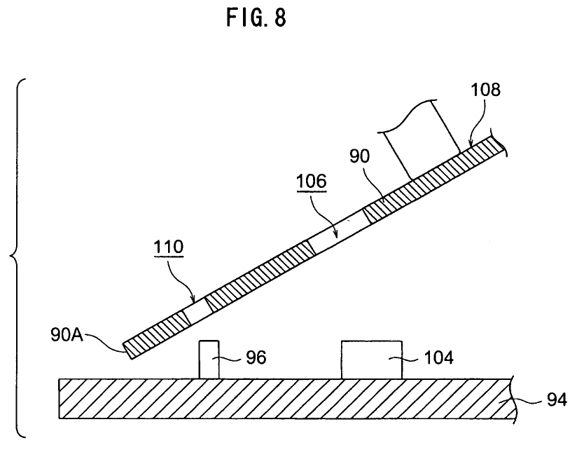

In FIG. 8, as a comparative example, a state is shown in which a flexible circuit board 108, which includes a (circular) positioning hole 110 of substantially the same diameter as the positioning pin 96, is positioned at the electronic component 94. In this comparative example in which the positioning hole 110 has substantially the same diameter as the positioning pin 96, if the positioning hole 110 is offset in the lateral direction (even a little), the positioning pin 96 will not enter therein.

In contrast, in the present exemplary embodiment, the broad portions 102 are formed at the leading end side of the direction of movement when the flexible circuit board 88 is moved relative to the electronic component 94. As a result, the task of positioning the flexible circuit board 88 relative to the electronic component 94 is made easier. For example, if the positioning holes 92A and 92B are relatively offset in the lateral direction with respect to the positioning pins 96A and 96B, provided this is within the range of the broad portions 102, this offset is absorbed, and the positioning pin 96A is accommodated in the positioning hole 92A and the positioning pin 96B is accommodated in the positioning hole 92B.

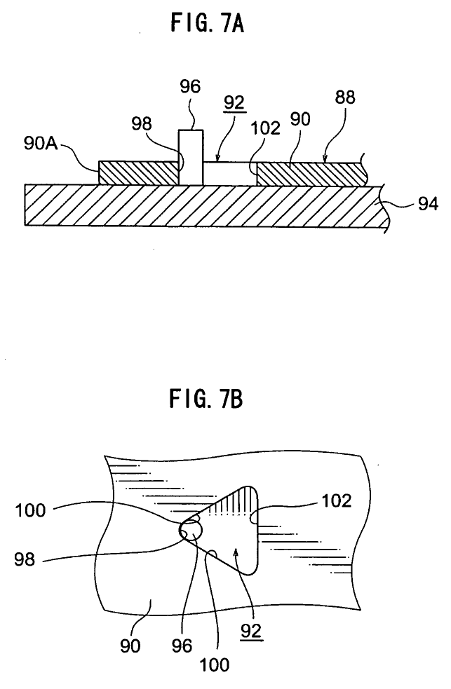

Further, as the flexible circuit board body 90 is moved in the direction of arrow M1, as shown in FIG. 7A and FIG. 7B, the outer peripheral faces of the positioning pins 96A and 96B abut against the circular arc faces 98 of the positioning holes 92A and 92B and the movement is blocked. Correspondingly, the flexible circuit board 88 is positioned relative to the electronic component 94 (a positioning step).

Then, as shown in FIG. 9, the joining protrusion 104 is mated with the joining hole 106, and a crimping process or the like is applied to a distal end portion of the joining protrusion 104. Thus, the flexible circuit board 88 is joined (fixed) in a state of being positioned relative to the electronic component 94. In addition, the flexible circuit board 88 and the electronic component 94 are electrically connected. Further electrical connection portions may subsequently be configured with solder or the like between the flexible circuit board 88 and the electronic component 94 or the driver circuit board 84.

When the flexible circuit board 88 has been positioned relative to the electronic component 94 in this manner, the outer peripheral faces of the positioning pins 96A and 96B are in surface contact with the circular arc faces 98 of the positioning holes 92A and 92B. Therefore, in the structure of the present exemplary embodiment, these have lower pressure acting on contact portions compared to structures that make point contact or line contact. Consequently, local loads on the positioning holes 92A and 92B from the positioning pins 96A and 96B are smaller.

As is seen from FIG. 7B, when the positioning pins 96A and 96B are in surface contact with the circular arc faces 98, the respective inner surfaces 100 of the positioning holes 92A and 92B face and make contact with the positioning pins 96A and 96B at angles as viewed in the lateral direction. Therefore, movement of the flexible circuit board body 90 relative to the electronic component 94 in the lateral direction is blocked. Thus, the flexible circuit board 88 is positioned relative to the electronic component 94 in both a longitudinal direction (the direction of arrow M1) and the lateral direction.

Furthermore, of the three corners of each of the positioning holes 92A and 92B, the other two corner portions are curved as well as the circular arc face 98. Therefore, local loading on the flexible circuit board body 90 from the inner sides of the positioning holes 92A and 92B is suppressed. As a result, cracking, damage and the like of the flexible circuit board body 90 may be avoided.

### Second Embodiment

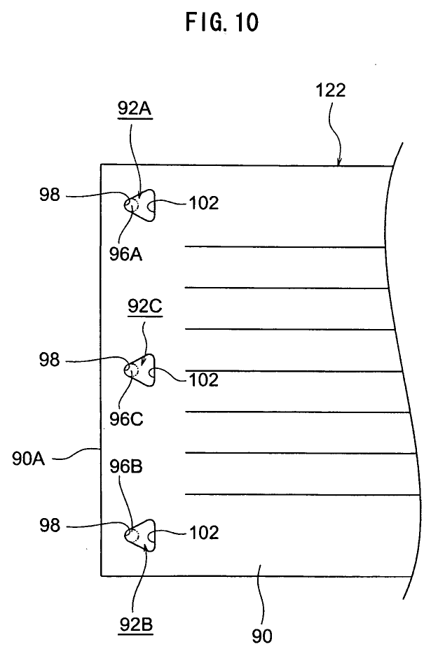

FIG. 10 shows a flexible circuit board 122 of a second exemplary embodiment of the present invention. In the exemplary embodiments hereinafter, structural elements, members that are the same as in the first exemplary embodiment are assigned with the same reference numerals and detailed descriptions thereof will be omitted.

In the flexible circuit board 122 of the second exemplary embodiment, in addition to the positioning holes 92A and 92B at positions in vicinities of the two lateral direction ends of the flexible circuit board body 90, a positioning hole 92C is formed at a lateral direction middle region. Meanwhile, a positioning pin 96C that fits into the positioning hole 92C is added to the positioning pins 96 of the electronic component 94 (not shown in FIG. 10 but see FIG. 3A and the like that illustrate the first exemplary embodiment).

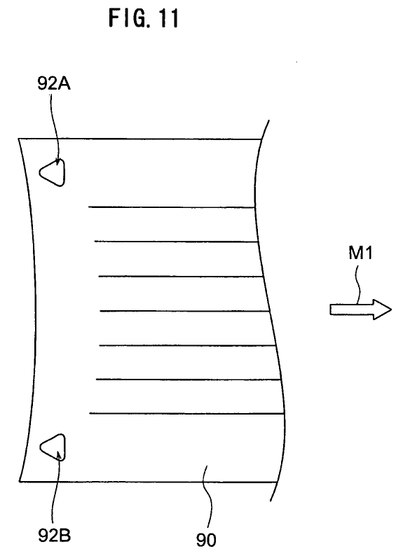

Now, when the flexible circuit board body 90 is moved in the direction of arrow M1 relative to the electronic component 94 as shown in FIG. 11, the lateral direction middle region of the flexible circuit board body 90 is more greatly deformed in the direction of arrow M1 than the two lateral direction end regions. However, if the positioning hole 92C is formed at the lateral direction middle region of the flexible circuit board body 90 as in the second exemplary embodiment, the positioning pin 96C is accommodated and positioned in the positioning hole 92C. As a result, the above-mentioned deformation of the flexible circuit board body 90 may be suppressed. Therefore, positioning of the lateral direction middle region of the flexible circuit board body 90 may be carried out more assuredly. Consequently, in the present exemplary embodiment, overall positioning of the flexible circuit board 122 may be carried out more accurately.

### Third Embodiment

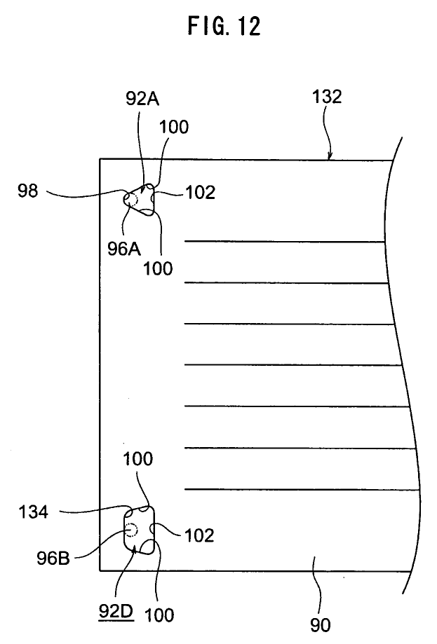

FIG. 12 shows a flexible circuit board 132 of a third exemplary embodiment of the present invention. One of the positioning holes 92A is formed in the isosceles triangle shape, as same in the first exemplary embodiment. However, another positioning hole 92D is formed in a trapezoid shape. Consequently, the trapezoid positioning hole 92D as a whole is formed to be broader than the positioning hole 92A. In addition, the positioning hole 92D is structured with a flat face 134 instead of the circular arc face 98.

Now, for a structure in which, for example, all of the positioning holes 92A and 92B are formed in triangular shapes as in the first exemplary embodiment, a case in which the positions of the positioning holes 92A and 92B and the positioning pins 96A and 96B are slightly offset is considered. In this case, even when the positioning pin 96A is positioned at the circular arc face 98 of the one positioning hole 92A, the positioning pin 96B may not be positioned at the circular arc face 98 of the other positioning hole 92B.

In contrast, if the one positioning hole 92D is formed as a trapezoid as in the present exemplary embodiment, the above-mentioned positional offset may be absorbed by the trapezoid positioning hole 92D. In the positioned state, a positioning pin 96D is in contact with the flat face 134. Meanwhile, the positioning pin 96A is in contact with the circular arc face 98 and the inner surfaces 100 of the triangular positioning hole 92A. Thus, positioning of the flexible circuit board body 90 in the lateral direction is possible.

### Fourth Embodiment

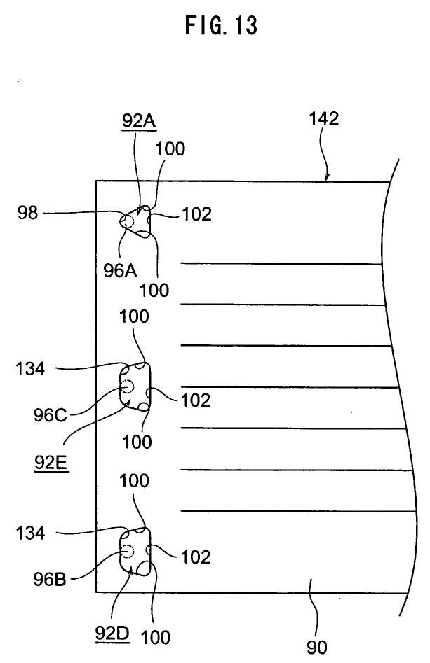

FIG. 13 shows a flexible circuit board 142 of a fourth exemplary embodiment of the present invention. In the fourth exemplary embodiment, similarly to the second exemplary embodiment, a total of three positioning holes are formed, at the two lateral direction vicinity regions and the middle region of the flexible circuit board body 90. In the present exemplary embodiment however, one of the positioning holes 92A is formed in a triangular shape and the other two positioning holes 92D and 92E are formed as trapezoids.

Thus, with a structure in which three or more positioning holes are formed in the lateral direction of the flexible circuit board body 90, plural positioning holes may be formed as trapezoids. However, it is preferable to form the structure such that at least one of the positioning holes is formed in a triangular shape and movements of the flexible circuit board body in the lateral direction are suppressed.

Anyway, in the exemplary embodiments described above, the positioning pins 96A, 96B and 96C are exemplified as circular rod shapes. However, shapes of positioning pins are not to be limited to this.

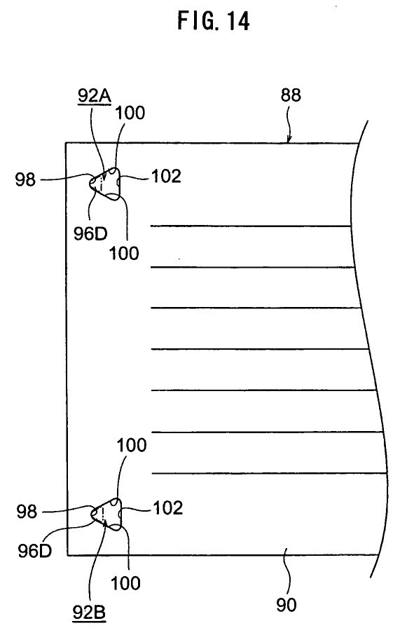

For example, FIG. 14 shows triangular rod-form positioning pins 96D. When each positioning pin 96D is viewed in plan view (viewed along the length direction thereof), a curve is provided at a tip portion thereof, with a radius of curvature the same as that of the circular arc face 98 of the positioning hole 92A or 92B. The positioning pin 96D makes surface contact with the circular arc face 98 of the triangular positioning hole 92A and the inner surfaces 100 at the two sides of the circular arc face 98. In FIG. 14, the flexible circuit board 88, with the same structure as in the first exemplary embodiment, is exemplified as the flexible circuit board. However, the present invention is not limited to the same.

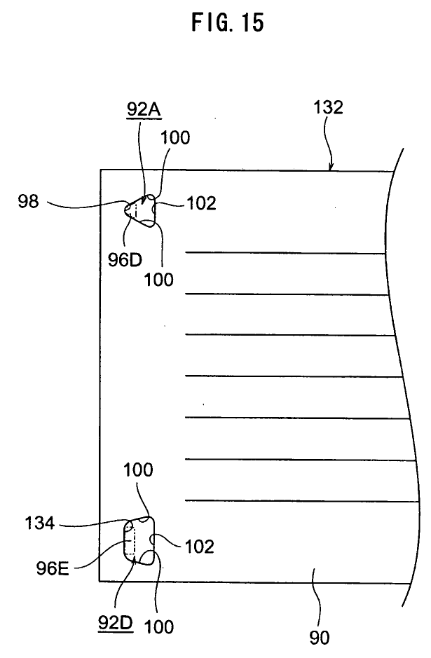

Further, in the example illustrated in FIG. 15, a positioning pin 96E has a quadrilateral rod shape. The positioning pin 96E makes surface contact with the flat face 134 at the one edge side of the trapezoid positioning hole 92C illustrated in FIG. 12. In FIG. 15, the positioning pin 96E has a substantially rectangular shape in plan view. However, the positioning pin 96E may have, for example, a trapezoid shape. Moreover, if surface contact is to be made with the flat face 134 at the one edge side of the positioning hole 92C, the shape of the positioning pin is not limited to a quadrilateral rod shape; a flat face portion that makes surface contact with the flat face 134 may be structured at the pin. Whatever the shape, a structure is formed such that, when the positioning pin is viewed in plan view (viewed along the length direction thereof), no corner portions are present at least at a portion that makes contact with the positioning hole. With such a structure, local loading on the flexible circuit board body may be suppressed. Here, the flexible circuit board 132, with the same structure as in the third exemplary embodiment, is exemplified as the flexible circuit board in FIG. 15 but this is not to be limiting.

A fatness of a positioning pin (a cross-sectional area when viewed in plan view) is not particularly limited as long as it may be accommodated in the positioning hole and the flexible circuit board may be positioned relative to the electronic component 94. Therefore, when the fatness of a pin is thin within a range having predetermined strength (stiffness), the pin will easily enter the positioning hole and this is preferable. A positioning pin does not need to have a constant cross-sectional area. A positioning pin may have, for example, a shape which gradually tapers to be thinner toward a distal end (upper end) thereof.

In the above descriptions, structures are formed with heights of the positioning pins being greater than the thickness of the flexible circuit board body 90. Therefore, compared with a structure in which a positioning pin is lower than the thickness of the flexible circuit board 88, a positioning pin is less likely to disengage when accommodated in a positioning hole. When the upper end of a positioning pin partially protrudes from the flexible circuit board body 90, the protruding portion may be crimped by the pushing jig 112 or the like. Therefore, the flexible circuit board may be fixed to the electronic component 94 at the positioning pins as well as the joining protrusion 104. Thus, the number of fixing points increases and the flexible circuit board and the electronic component may be more firmly fixed.

In the above descriptions, structures are exemplified in which the flexible circuit board 88 is connected with the driver circuit board 84 of the head unit 66. However, a connection object of the flexible circuit board 88 is not to be limited to this. For example, the connection object may be the control circuit board 86. Further, within the head unit 66, the flexible circuit board 88 may be employed for, for example, connection of the control circuit board 86 to individual wiring of the piezoelectric elements, electrical connection between the head unit 66 and external members, or the like. In such cases, positioning of various kinds of members can be facilitated by using the flexible circuit board 88 of the present invention. In particular, in a structure in which a nozzle pitch is tightened, spacing of the piezoelectric elements tightens correspondingly. Therefore, it is preferable to be able to accurately position the flexible circuit board with respect to the individual wiring of the piezoelectric elements with ease. That is, application of the present invention to the connection of a flexible circuit board to individual wiring of piezoelectric elements is preferable.

What is claimed is:

1. A flexible circuit board comprising:
a flexible circuit board; and
a positioning accommodation portion, formed at the flexible circuit board body, capable of accommodating a positioning protrusion portion provided at a corresponding member, to which the flexible circuit board body is joined, the positioning accommodation portion positioning the flexible circuit board body relative to the corresponding member,
wherein a broad portion is formed at the positioning accommodation portion, at which a leading end side of the positioning accommodation portion, with respect to a direction of movement of the flexible circuit board body relative to the corresponding member at a time of joining, is broader than a trailing end side.

2. The flexible circuit board according to claim 1, wherein a surface contact portion, which makes surface contact with the positioning protrusion portion, is formed at the trailing end side of the positioning accommodation portion.

3. The flexible circuit board according to claim 2, wherein the surface contact portion includes a circular arc face that makes surface contact, with a radius of curvature the same as the radius of curvature of an outer peripheral face of the positioning protrusion portion, which is formed in a circular rod shape.

4. The flexible circuit board according to claim 1, wherein a lateral direction contact portion is formed at the trailing end side of the positioning accommodation portion, the lateral direction contact portion making contact with the positioning protrusion portion in a lateral direction of the flexible circuit board, which intersects the movement direction.

5. The flexible circuit board according to claim 1, wherein at least one of the positioning accommodation portion is formed at each of a lateral direction middle region of the flexible circuit board body, which lateral direction intersects the movement direction, and two lateral direction end sides relative to the middle region.

6. The flexible circuit board according to claim 5, wherein a portion at the trailing end side of at least one of the plurality of positioning accommodation portions is a second broad portion, which is formed to be broader in the lateral direction than a portion at the trailing end side of another of the positioning accommodation portions.

7. A flexible circuit board positioning method for positioning a flexible circuit board at a corresponding member, the flexible circuit board including,
a flexible circuit board body; and
a positioning accommodation portion, formed at the flexible circuit board body, capable of accommodating a positioning protrusion portion provided at a corresponding member, to which the flexible circuit board body is joined, the positioning accommodation portion positioning the flexible circuit board body relative to the corresponding member, wherein a broad portion is formed at the positioning accommodation portion, at which a leading end side of the positioning accommodation portion, with respect to a direction of movement of the flexible circuit board body relative to the corresponding member at a time of joining, is broader than a trailing end side,
the flexible circuit board positioning method comprising:
accommodating the positioning protrusion portion in the broad portion by moving the moving the flexible circuit board relative to the corresponding member; and
positioning by moving the flexible circuit board further relative to the corresponding member and causing the trailing end side of the positioning accommodation portion to make contact with the positioning protrusion portion.

8. A flexible circuit board positioning structure comprising:
a flexible circuit board including
a flexible circuit board body, and
a positioning accommodation portion, formed at the flexible circuit board body, capable of accommodating a positioning protrusion portion provided at a corresponding member, to which the flexible circuit board body is joined, the positioning accommodation portion positioning the flexible circuit board body relative to the corresponding member, wherein a broad portion is formed at the positioning accommodation portion, at which a leading end side of the positioning accommodation portion, with respect to a direction of movement of the flexible circuit board body relative to the corresponding member at a time of joining, is broader than a trailing end side;
the corresponding member to which the flexible circuit board body is to be joined; and
the positioning protrusion portion provided at the corresponding member,
wherein the trailing end side of the positioning accommodation portion of the flexible circuit board body is positioned by coming into contact with the positioning protrusion portion.

9. A droplet ejection head comprising:
a droplet ejection head body for ejecting droplets;
a circuit substrate provided at the droplet ejection head body; and
a flexible circuit board joined to the circuit substrate, the flexible circuit board including
a flexible circuit board body, and
a positioning accommodation portion, formed at the flexible circuit board body, capable of accommodating a positioning protrusion portion provided at the circuit substrate, to which the flexible circuit board body is joined, the positioning accommodation portion positioning the flexible circuit board body relative to the circuit substrate, wherein a broad portion is formed at the positioning accommodation portion, at which a leading end side of the positioning accommodation portion, with respect to a direction of movement of the flexible circuit board body relative to the circuit substrate at a time of joining, is broader than a trailing end side.

10. An image forming device comprising:
a conveyance apparatus that conveys a recording sheet; and
a droplet ejection head, which ejects droplets onto the recording sheet conveyed by the conveyance apparatus, the droplet ejection head including
a droplet ejection head body for ejecting droplets,
a circuit substrate provided at the droplet ejection head body, and
a flexible circuit board joined to the circuit substrate, the flexible circuit board including
a flexible circuit board body, and
a positioning accommodation portion, formed at the flexible circuit board body, capable of accommodating a positioning protrusion portion provided at the circuit substrate, to which the flexible circuit board body is joined, the positioning accommodation portion positioning the flexible circuit board body relative to the circuit substrate, wherein a broad portion is formed at the positioning accommodation portion, at which a leading end side of the positioning accommodation portion, with respect to a direction of movement of the flexible circuit board body relative to the circuit substrate at a time of joining, is broader than a trailing end side.
